(19) United States
(12) Patent Application Publication
(10) Pub. No.: US 2023/0178696 A1
(43) Pub. Date: Jun. 8, 2023

(54) OPTOELECTRONIC ASSEMBLY

(71) Applicant: Infineon Technologies AG, Neubiberg (DE)

(72) Inventors: Dietrich Bonart, Bad Abbach (DE); Alexander Heinrich, Bad Abbach (DE); Bernhard Weidgans, Bernhardswald (DE)

(21) Appl. No.: 17/540,373

(22) Filed: Dec. 2, 2021

(51) Int. Cl. H01L 33/62; H01L 25/075

(52) U.S. Cl. CPC H01L 33/62; H01L 25/0753

(57) ABSTRACT

An optoelectronic assembly includes: a plurality of semiconductor light sources, each one of the semiconductor light sources including a plurality of pads; and a driver device configured to drive each one of the semiconductor light sources. For each pad of each semiconductor light source, the driver device has a corresponding pad facing the pad of the semiconductor light source to form a pair of connectable pads. For each pair of connectable pads, a first pad of the pair of connectable pads has a first shape and a second pad of the pair of connectable pads has a second shape complementary to the first shape such that the first pad and the second pad form a mated connection when brought into contact with one another. Corresponding driver device and semiconductor light sources are also described.

### BACKGROUND

Attaching discrete LED (light-emitting diode) chips (dies) to a driver chip to produce an optoelectronic assembly is challenging from a manufacturing perspective, especially with respect to both alignment and re-work of defective LED chips. Thus, there is a need for an improved technique for producing optoelectronic assemblies.

### SUMMARY

According to an embodiment of an optoelectronic assembly, the optoelectronic assembly comprises: a plurality of semiconductor light sources, each one of the semiconductor light sources comprising a plurality of pads; and a driver device configured to drive each one of the semiconductor light sources, wherein for each pad of each semiconductor light source, the driver device has a corresponding pad facing the pad of the semiconductor light source to form a pair of connectable pads, wherein for each pair of connectable pads, a first pad of the pair of connectable pads has a first shape and a second pad of the pair of connectable pads has a second shape complementary to the first shape such that the first pad and the second pad form a mated connection when brought into contact with one another.

According to an embodiment of a driver device, the driver device comprises: a semiconductor substrate; driver circuitry formed in and/or on the semiconductor substrate and configured to drive a plurality of semiconductor light sources; and a plurality of pads configured to provide an electrical interface for the driver device to the semiconductor light sources, wherein for each pad of the driver device, the pad has a first shape that is complementary to a second shape of a semiconductor light source pad to which the pad of the driver device is to be connected, such that the pad of the driver device and the semiconductor light source pad to which the pad of the driver device is to be connected form a mated connection when brought into contact with one another.

According to an embodiment of a semiconductor light source, the semiconductor light source comprises: a semiconductor substrate; an electroluminescent element included in the semiconductor substrate and configured to emit light in response to an electric current or an electric field; and a plurality of pads configured to provide an electrical interface for the semiconductor light source to a driver device, wherein for each pad of the semiconductor light source, the pad has a first shape that is complementary to a second shape of a driver device pad to which the pad of the semiconductor light source is to be connected, such that the pad of the semiconductor light source and the driver device pad to which the pad of the semiconductor light source is to be connected form a mated connection when brought into contact with one another.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A and 1B illustrate an embodiment of an optoelectronic assembly, where FIG. 1A illustrates a top plan view of the optoelectronic assembly and FIG. 1B illustrates a partial cross-sectional view of the optoelectronic assembly along the line labelled A-A′ in FIG. 1A.

FIG. 2 illustrates a cross-sectional view of another embodiment of an optoelectronic assembly.

FIGS. 3A and 3B illustrate cross-sectional views of an embodiment of a method of producing a driver device pad for an optoelectronic assembly.

FIGS. 4A through 4C illustrate an embodiment of a mated connection to be realized by pairs of complementary-shaped pads of an optoelectronic assembly, where FIG. 4A illustrates a top plan view of a semiconductor light source pad, FIG. 4B illustrates a top plan view of a driver device pad, and FIG. 4C illustrates a cross-sectional view of two adjacent pairs of connectable pads during assembly or testing of the optoelectronic assembly.

FIGS. 5A through 5C illustrate another embodiment of a mated connection to be realized by pairs of complementary-shaped pads of an optoelectronic assembly, where FIG. 5A illustrates a top plan view of a semiconductor light source pad, FIG. 5B illustrates a top plan view of a driver device pad, and FIG. 5C illustrates a cross-sectional view of two adjacent pairs of connectable pads during assembly or testing of the optoelectronic assembly.

FIGS. 6A through 6C illustrate another embodiment of a mated connection to be realized by pairs of complementary-shaped pads of an optoelectronic assembly, where FIG. 6A illustrates a top plan view of a semiconductor light source pad, FIG. 6B illustrates a top plan view of a driver device pad, and FIG. 6C illustrates a cross-sectional view of two adjacent pairs of connectable pads during assembly or testing of the optoelectronic assembly.

FIGS. 7A through 7C illustrate another embodiment of a mated connection to be realized by pairs of complementary-shaped pads of an optoelectronic assembly, where FIG. 7A illustrates a top plan view of a semiconductor light source pad, FIG. 7B illustrates a top plan view of a driver device pad, and FIG. 7C illustrates a cross-sectional view of two adjacent pairs of connectable pads during assembly or testing of the optoelectronic assembly.

FIGS. 8A through 8C illustrate another embodiment of a mated connection to be realized by pairs of complementary-shaped pads of an optoelectronic assembly, where FIG. 8A illustrates a top plan view of a semiconductor light source pad, FIG. 8B illustrates a top plan view of a driver device pad, and FIG. 8C illustrates a cross-sectional view of two adjacent pairs of connectable pads during assembly or testing of the optoelectronic assembly.

FIGS. 9A through 9C illustrate another embodiment of a mated connection to be realized by pairs of complementary-shaped pads of an optoelectronic assembly, where FIG. 9A illustrates a top plan view of a semiconductor light source pad, FIG. 9B illustrates a top plan view of a driver device pad, and FIG. 9C illustrates a cross-sectional view of two adjacent pairs of connectable pads during assembly or testing of the optoelectronic assembly.

### DETAILED DESCRIPTION

Described herein are embodiments of an optoelectronic assembly, semiconductor light sources for use in the optoelectronic assembly, and a driver device for the semiconductor light sources. For each pad of each semiconductor light source, the driver device has a corresponding pad facing the pad of the semiconductor light source to form a pair of connectable pads. For each pair of connectable pads, a first pad of the pair of connectable pads has a first shape and a second pad of the pair of connectable pads has a second shape complementary to the first shape such that the first and second pads form a mated connection when brought into contact with one another. The complementary pad shapes allow for lateral guidance when bringing the semiconductor light sources and the driver device together. That is, alignment between the semiconductor light sources and the driver device is ensured by the complementary-shaped pads. Hence, production of the optoelectronic assembly is simplified, particularly in the case of discrete semiconductor light source chips (dies).

Described next, with reference to the figures, are exemplary embodiments of the optoelectronic assembly, the semiconductor light sources included in the optoelectronic assembly, and the driver device for the semiconductor light sources.

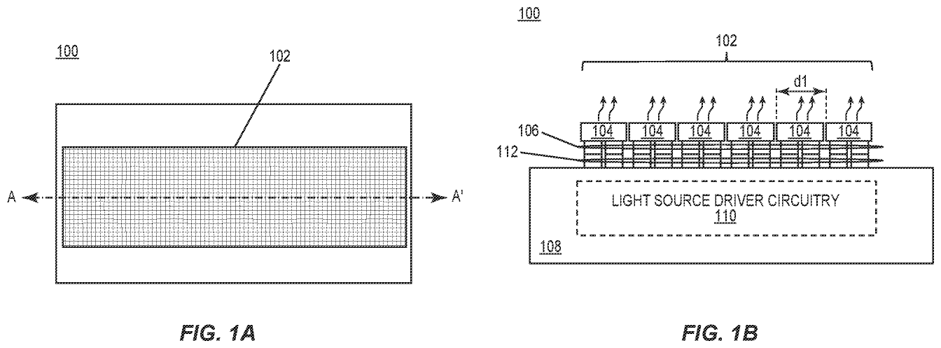

FIGS. 1A and 1B illustrate an embodiment of an optoelectronic assembly 100. FIG. 1A illustrates a top plan view of the optoelectronic assembly 100. FIG. 1B illustrates a partial cross-sectional view of the optoelectronic assembly 100 along the line labelled A-A′ in FIG. 1A.

The optoelectronic assembly 100 includes semiconductor light sources 102. Photonic emission by each semiconductor light source 102 is indicated in FIG. 1B by a pair of squiggly lines with arrows. Each light source 102 includes an electroluminescent element 104 included in a semiconductor substrate and configured to emit light in response to an electric current or an electric field.

The semiconductor light sources 102 may be arranged in an x-by-y array where x is a positive integer greater than or equal to 1 and y is a positive integer greater than or equal to 1. For example, the semiconductor light sources 102 may be arranged in a 250×70 ‘pixel’ array for a resolution of about 16K. This, however, is just an example. In general, the optoelectronic assembly 100 may include tens, hundreds, thousands, or even more semiconductor light sources 102.

According to the embodiment illustrated in FIGS. 1A and 1B, the semiconductor light sources 102 are implemented as discrete semiconductor chips (dies) such as LED chips, e.g., GaN LED chips, where each LED chip includes a semiconductor substrate with an electroluminescent element 104 included in the semiconductor substrate. The semiconductor light sources 102 are spaced apart from one another by a defined pitch dl such as, e.g., 50 μm. This is just an example, however, and individual ones or groups of the semiconductor light sources 102 may be spaced apart from other ones of the semiconductor light sources 102 by the same or different distance. Each semiconductor light source 102 includes pads 106 for making electrical contact to the respective light sources 102.

The optoelectronic assembly 100 also includes a driver device 108 for driving each one of the semiconductor light sources 102. The driver device 108 may individually drive each semiconductor light source 102 or may separately drive different groups of the semiconductor light sources 102. In one embodiment, the driver device 108 is implemented as a semiconductor wafer such as a Si wafer and several optoelectronic assemblies 100 are produced from the same wafer upon singulation/dicing. Alternatively, the driver device 108 may be implemented as a semiconductor chip.

In either case, the driver device 108 includes driver circuitry 110 for driving/controlling the semiconductor light sources 102. For example, the driver circuitry 110 for driving/controlling the semiconductor light sources 102 may include circuitry for controlling the amount of current flowing through individual ones and/or groups of the semiconductor light sources 102 to provide a desired brightness, circuitry for limiting current to prevent damaging the semiconductor light sources 102, dimming circuitry, etc. The driver circuitry 110 may be formed partly in a semiconductor substrate of the driver device 108 and partly in metal layers provided above the semiconductor substrate, for example. That is, the driver device 108 may have a standard semiconductor chip or wafer construction.

For each pad 106 of each semiconductor light source 102, the driver device 108 has a corresponding pad 112 facing the pad 106 of the semiconductor light source 102 to form a pair of connectable pads 106/112. For each pair of connectable pads 106/112, a first pad of the pair of connectable pads 106/112 has a first shape and a second pad of the pair of connectable pads 106/112 has a second shape complementary to the first shape such that the first pad and the second pad form a mated connection when brought into contact with one another. The mated connections enabled by the pairs of connectable pads 106/112 may form a repairable/temporary interconnect and/or a permanent interconnect. Various embodiments of the pad shapes and resulting mated connections are described later herein in more detail. With such complementary-shaped pads 106, 112, lateral guidance is significantly improved when bringing the semiconductor light sources 102 and the driver device 108 together.

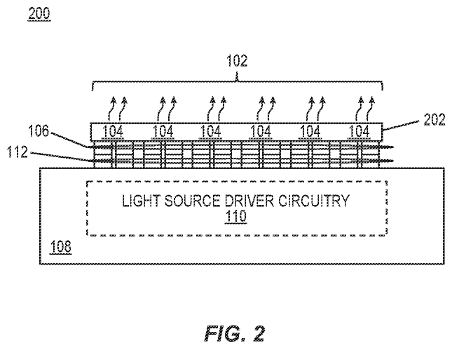

FIG. 2 illustrates a cross-sectional view of another embodiment of an optoelectronic assembly 200. The embodiment illustrated in FIG. 2 is similar to the embodiment illustrated in FIGS. 1A and 1B. Differently, however, the semiconductor light sources 102 are included in one semiconductor die 202. Like the embodiment illustrated in FIGS. 1A and 1B, the semiconductor light sources 102 and the driver device 108 of the optoelectronic assembly 200 have complementary-shaped pads 106, 112 that form mated connections when the semiconductor light sources 102 and the driver device 108 are brought into contact with one another during assembly or testing.

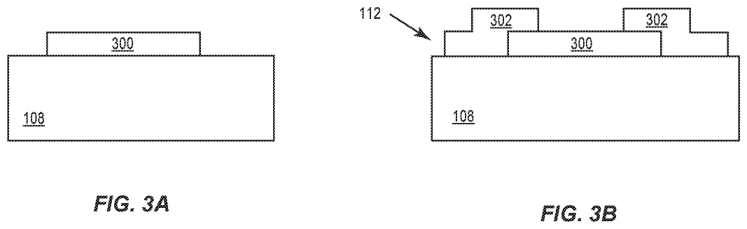

FIGS. 3A and 3B illustrate an embodiment of a method of producing the driver device pads 112 in the region of one pad 112. In FIG. 3A, a base 300 of the driver device pad 112 is formed from a first metal or metal alloy. For example, the base 300 may comprise Au, NiP, NiPPdAu, Ag, Cu, etc. The base 300 may be formed by a metal deposition process such as sputtering, for example. In FIG. 3B, a patterned structure 302 is formed on the base 300. The patterned structure 302 comprises a second metal or metal alloy and has a different shape than the base 300. For example, the patterned structure 302 may comprise Au, NiP, NiPPdAu, Ag, Cu, etc.

In one embodiment, the patterned structure 302 is formed by a ‘lift-off’ process which includes deposition and development of a resist. A metal or metal alloy is then deposited on each open area where the resist was removed and on the remaining part of the resist. The resist is then removed by lifting off, leaving the deposited metal or metal alloy only on the open areas previously uncovered by the resist. Gold (Au), e.g., may be sputtered on a resist and then removed by such a lift-off process to form the patterned structure 302.

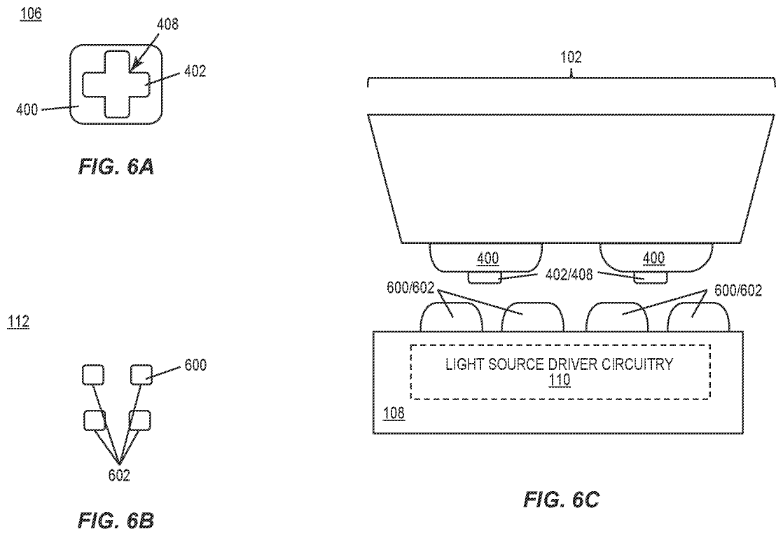

In another embodiment, galvanic plating is used to form the patterned structure 302. In yet other embodiments, the driver device bond pad 112 is implemented as a single metal or metal alloy layer. That is, each pad 112 of the driver device 108 comprises a single patterned metal or metal alloy layer, e.g., as shown in FIGS. 6B-6C.

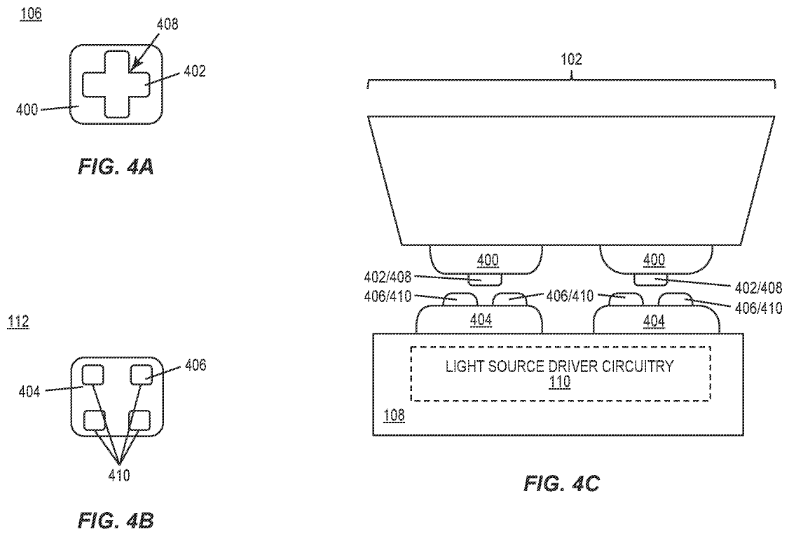

FIGS. 4A through 4C illustrate an embodiment of the mated connection to be realized by each pair of complementary-shaped pads 106, 112. FIG. 4A illustrates a top plan view of a semiconductor light source pad 106. FIG. 4B illustrates a top plan view of a driver device pad 112. FIG. 4C illustrates a cross-sectional view of two adjacent pairs of connectable pads 106/112 during assembly or testing. According to this embodiment, the semiconductor light source pad 106 includes a base 400 comprising a first metal or metal alloy and a patterned structure 402 on the base 400 and that comprises a second metal or metal alloy. The patterned structure 402 of the semiconductor light source pad 106 has a different shape than the base 400 of the semiconductor light source pad 106. In one embodiment, the patterned structure 402 of the semiconductor light source pad 106 is formed of a relatively soft metal such as solder, Sn, In, In alloy, NiP with Sn or In islands, Pb solder such as, e.g., PbSnAg, etc. and the base 400 of the semiconductor light source pad 106 comprises a metal or metal alloy having a higher hardness than the relatively soft metal of the patterned structure 402, e.g., such as Au, NiP, NiPPdAu, Ag, Cu, etc. Alternatively, the patterned structure 402 and base 400 of the semiconductor light source pad 106 comprise the same metal or metal alloy.

The driver device pad 112 similarly includes a base 404 comprising a first metal or metal alloy and a patterned structure 406 on the base 404 and that comprises a second metal or metal alloy. The patterned structure 406 of the driver device pad 112 has a different shape than the base 404 of the driver device pad 112. In one embodiment, the patterned structure 406 of the driver device pad 112 comprises Au and the base 404 of the driver device pad 112 comprises a metal or metal alloy having a higher hardness than the solder, e.g., such as Au, NiP, NiPPdAu, Cu, etc. Alternatively, the patterned structure 406 and the base 404 of the driver device pad 112 comprise the same metal or metal alloy. The driver device pad 112 may have a higher hardness than the semiconductor light source pad 106. For example, the patterned structure 402 of the semiconductor light source pad 106 may comprise solder and the patterned structure 406 of the driver device pad 112 may comprise Au.

The patterned structure 402 of the semiconductor light source pad 106 defines the shape of the semiconductor light source pad 106, and the patterned structure 406 of the driver device pad 112 defines the shape of the driver device pad 112. For example, as shown in FIG. 4A, the patterned structure 402 of the semiconductor light source pad 106 may have a cross feature 408 and the patterned structure 406 of each driver device pad 112 may have four spaced apart posts 410 configured to receive the cross feature 408 of the semiconductor light source pad 106 during assembly or testing. The cross feature 408 and complementarily shaped posts 410 for each pair of complementary-shaped pads 106, 112 allow for lateral guidance when bringing the semiconductor light sources 102 and the driver device 108 together, as illustrated in FIG. 4C.

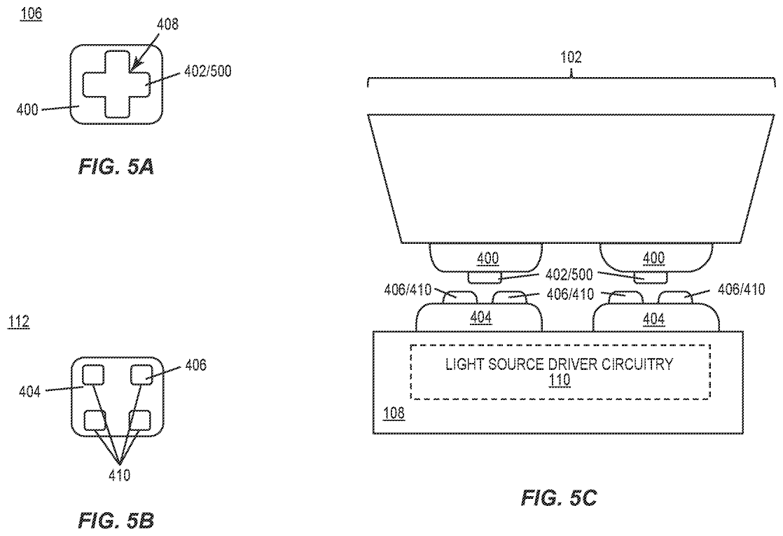

FIGS. 5A through 5C illustrate another embodiment of the mated connection to be realized by each pair of complementary-shaped pads 106, 112. FIG. 5A illustrates a top plan view of a semiconductor light source pad 106. FIG. 5B illustrates a top plan view of a driver device pad 112. FIG. 5C illustrates a cross-sectional view of two adjacent pairs of connectable pads 106/112 during assembly or testing. The embodiment illustrated in FIGS. 5A-5C is similar to the embodiment illustrated in FIGS. 4A-4C. Differently, however, the patterned structure 402 that forms the cross feature 408 of the semiconductor light source pad 106 is not made of solder. Instead, the patterned structure 402 is made of a non-solder metal or metal alloy 500 that can be patterned such as Au, NiP, NiPPdAu, Ag, Cu, etc.

FIGS. 6A through 6C illustrate another embodiment of the mated connection to be realized by each pair of complementary-shaped pads 106, 112. FIG. 6A illustrates a top plan view of a semiconductor light source pad 106. FIG. 6B illustrates a top plan view of a driver device pad 112. FIG. 6C illustrates a cross-sectional view of two adjacent pairs of connectable pads 106/112 during assembly or testing. The embodiment illustrated in FIGS. 6A-6C is similar to the embodiment illustrated in FIGS. 4A-4C. Differently, however, the driver device pad 112 comprises a single patterned metal or metal alloy layer 600. For example, the single patterned metal or metal alloy layer 600 may comprise Au, NiP, NiPPdAu, Ag, Cu, etc. In the case of a cross feature 408 for the semiconductor light source pad 106, the single metal or metal alloy layer 600 of the driver device pad 112 may be patterned into four spaced apart posts 602 configured to receive the cross feature 408 of the semiconductor light source pad 106 during assembly or testing, as shown in FIG. 6C.

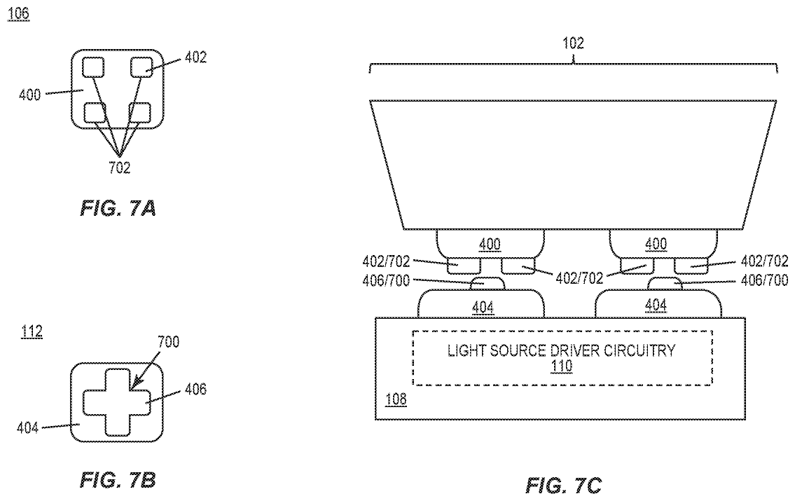

FIGS. 7A through 7C illustrate another embodiment of the mated connection to be realized by each pair of complementary-shaped pads 106, 112. FIG. 7A illustrates a top plan view of a semiconductor light source pad 106. FIG. 7B illustrates a top plan view of a driver device pad 112. FIG. 7C illustrates a cross-sectional view of two adjacent pairs of connectable pads 106/112 during assembly or testing. The embodiment illustrated in FIGS. 7A-7C is similar to the embodiment illustrated in FIGS. 4A-4C. Differently, however, the patterned structure 406 of the driver device pad 112 has a cross feature 700 and the patterned structure 402 of the semiconductor light source pad 106 has four spaced apart posts 702 configured to receive the cross feature 700 of the driver device pad 112 during assembly or testing. The cross feature 700 and complementarily shaped posts 702 for each pair of complementary-shaped pads 106, 112 allow for lateral guidance when bringing the semiconductor light sources 102 and the driver device 108 together, as illustrated in FIG. 7C.

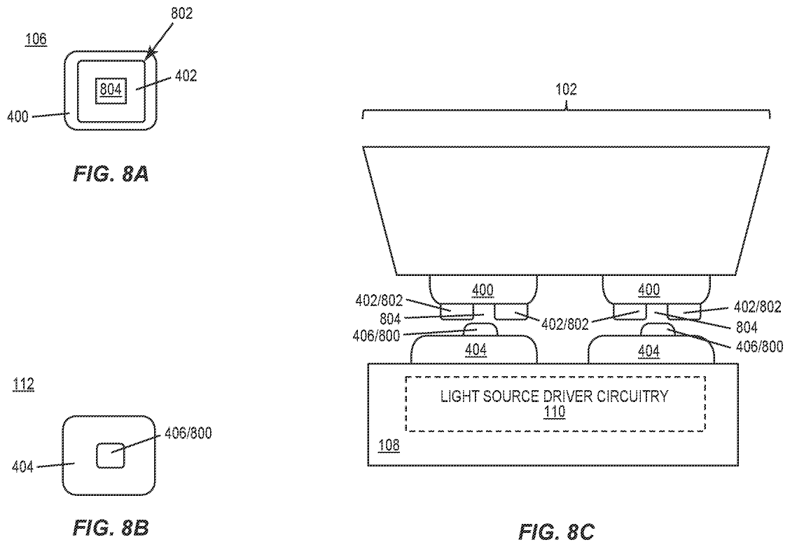

FIGS. 8A through 8C illustrate another embodiment of the mated connection to be realized by each pair of complementary-shaped pads 106, 112. FIG. 8A illustrates a top plan view of a semiconductor light source pad 106. FIG. 8B illustrates a top plan view of a driver device pad 112. FIG. 8C illustrates a cross-sectional view of two adjacent pairs of connectable pads 106/112 during assembly or testing. The embodiment illustrated in FIGS. 8A-8C is similar to the embodiment illustrated in FIGS. 4A-4C. Differently, however, the patterned structure 406 of the driver device pad 112 has a columnar feature 800 and the patterned structure 402 of the semiconductor light source pad 106 has a wall feature 802 that defines an open interior space 804 configured to receive the columnar feature 800 of the driver device pad 112 during assembly or testing. The wall feature 802 and complementarily columnar feature 800 for each pair of complementary-shaped pads 106, 112 allow for lateral guidance when bringing the semiconductor light sources 102 and the driver device 108 together, as illustrated in FIG. 8C.

The wall feature 802 of the semiconductor light source pad 106 may be made of solder and the columnar feature 800 of the driver device pad 112 may be made of a metal or metal alloy having a higher melting temperature than solder, for example. If instead the columnar feature 800 of the driver device pad 112 is made of solder and the wall feature 802 of the semiconductor light source pad 106 is made of a metal or metal alloy having a higher melting temperature than solder, the wall feature 802 prevents solder overflow during the solder reflow/joining process.

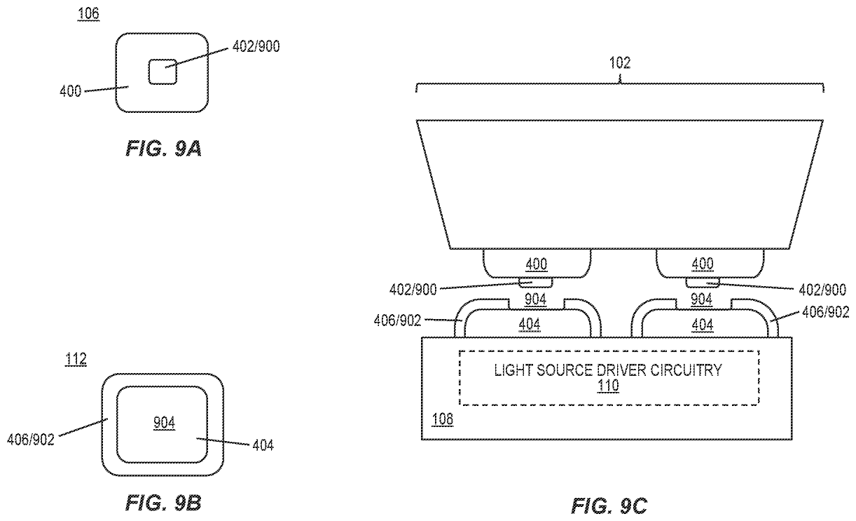

FIGS. 9A through 9C illustrate another embodiment of the mated connection to be realized by each pair of complementary-shaped pads 106, 112. FIG. 9A illustrates a top plan view of a semiconductor light source pad 106. FIG. 9B illustrates a top plan view of a driver device pad 112. FIG. 9C illustrates a cross-sectional view of two adjacent pairs of connectable pads 106/112 during assembly or testing. The embodiment illustrated in FIGS. 9A-9C is similar to the embodiment illustrated in FIGS. 4A-4C. Differently, however, the patterned structure 402 of the semiconductor light source pad 106 has a columnar feature 900 and the patterned structure 406 of the driver device pad 112 has a wall feature 902 that defines an open interior space 904 configured to receive the columnar feature 900 of the semiconductor light source pad 106 during assembly or testing. The wall feature 902 and complementarily columnar feature 900 for each pair of complementary-shaped pads 106, 112 allow for lateral guidance when bringing the semiconductor light sources 102 and the driver device 108 together, as illustrated in FIG. 9C. The columnar feature 900 of the semiconductor light source pad 106 may be made of solder and the wall feature 902 of the driver device pad 112 may be made of a metal or metal alloy having a higher melting temperature than solder, e.g., such that the wall feature 902 prevents solder overflow during the solder reflow/joining process.

Although the present disclosure is not so limited, the following numbered examples demonstrate one or more aspects of the disclosure.

Example 1. An optoelectronic assembly, comprising: a plurality of semiconductor light sources, each one of the semiconductor light sources comprising a plurality of pads; and a driver device configured to drive each one of the semiconductor light sources, wherein for each pad of each semiconductor light source, the driver device has a corresponding pad facing the pad of the semiconductor light source to form a pair of connectable pads, wherein for each pair of connectable pads, a first pad of the pair of connectable pads has a first shape and a second pad of the pair of connectable pads has a second shape complementary to the first shape such that the first pad and the second pad form a mated connection when brought into contact with one another.

Example 2. The optoelectronic assembly of example 1, wherein each pad of the driver device comprises: a base comprising a first metal or metal alloy; and a patterned structure on the base and that comprises a second metal or metal alloy, wherein the patterned structure has a different shape than the base.

Example 3. The optoelectronic assembly of example 1, wherein each pad of the driver device comprises: a single patterned metal or metal alloy layer.

Example 4. The optoelectronic assembly of any of examples 1 through 3, wherein each pad of each semiconductor light source comprises: a base comprising a first metal or metal alloy; and a patterned structure on the base and that comprises a second metal or metal alloy, wherein the patterned structure has a different shape than the base.

Example 5. The optoelectronic assembly of example 4, wherein the patterned structure is formed of solder and the base comprises a metal or metal alloy having a higher hardness than the solder, or wherein the patterned structure and the base comprise a same metal or metal alloy.

Example 6. The optoelectronic assembly of any of examples 1 through 5, wherein for each pair of connectable pads, both the first pad and the second pad of the pair of connectable pads comprises: a base comprising a first metal or metal alloy; and a patterned structure on the base and that comprises a second metal or metal alloy, wherein the patterned structure of the first pad of the pair of connectable pads defines the first shape, wherein the patterned structure of the second pad of the pair of connectable pads defines the second shape.

Example 7. The optoelectronic assembly of any of examples 1 through 6, wherein the first shape and/or the second shape allows for lateral guidance when bringing the plurality of semiconductor light sources and the driver device together.

Example 8. The optoelectronic assembly of any of examples 1 through 7, wherein for each pair of connectable pads, the first pad or the second pad of the pair of connectable pads has a cross feature and the other one of the first pad or the second pad of the pair of connectable pads has four spaced apart posts configured to receive the cross feature.

Example 9. The optoelectronic assembly of any of examples 1 through 7, wherein for each pair of connectable pads, the first pad or the second pad of the pair of connectable pads has a columnar feature and the other one of the first pad or the second pad of the pair of connectable pads has a wall feature that defines an open interior space configured to receive the columnar feature.

Example 10. The optoelectronic assembly of any of examples 1 through 7, wherein for each pair of connectable pads, the first pad or the second pad of the pair of connectable pads has a columnar feature and the other one of the first pad or the second pad of the pair of connectable pads has a recess feature configured to receive the columnar feature.

Example 11. The optoelectronic assembly of any of examples 1 through 10, wherein the pads of the driver device have a higher hardness than the pads of the semiconductor light sources.

Example 12. The optoelectronic assembly of any of examples 1 through 11, wherein for each pair of connectable pads, the first shape of the first pad of the pair of connectable pads is patterned from solder and the second shape of the second pad of the pair of connectable pads is patterned from a metal or metal alloy having a higher hardness than solder.

Example 13. A driver device, comprising: a semiconductor substrate; driver circuitry formed in and/or on the semiconductor substrate and configured to drive a plurality of semiconductor light sources; and a plurality of pads configured to provide an electrical interface for the driver device to the semiconductor light sources, wherein for each pad of the driver device, the pad has a first shape that is complementary to a second shape of a semiconductor light source pad to which the pad of the driver device is to be connected, such that the pad of the driver device and the semiconductor light source pad to which the pad of the driver device is to be connected form a mated connection when brought into contact with one another.

Example 14. The driver device of example 13, wherein each pad of the driver device comprises: a base comprising a first metal or metal alloy; and a patterned structure on the base and that comprises a second metal or metal alloy, wherein the patterned structure has a different shape than the base.

Example 15. The driver device of example 13, wherein each pad of the driver device comprises: a single patterned metal or metal alloy layer.

Example 16. The driver device of any of examples 13 through 15, wherein each pad of the driver device has a cross feature or four spaced apart posts configured to receive the cross feature.

Example 17. The driver device of any of examples 13 through 15, wherein each pad of the driver device has a columnar feature or a wall feature that defines an open interior space configured to receive the columnar feature.

Example 18. The driver device of any of examples 13 through 15, wherein each pad of the driver device has a columnar feature or a recess feature configured to receive the columnar feature.

Example 19. A semiconductor light source, comprising: a semiconductor substrate; an electroluminescent element included in the semiconductor substrate and configured to emit light in response to an electric current or an electric field; and a plurality of pads configured to provide an electrical interface for the semiconductor light source to a driver device, wherein for each pad of the semiconductor light source, the pad has a first shape that is complementary to a second shape of a driver device pad to which the pad of the semiconductor light source is to be connected, such that the pad of the semiconductor light source and the driver device pad to which the pad of the semiconductor light source is to be connected form a mated connection when brought into contact with one another.

Example 20. The semiconductor light source of example 19, wherein each pad of the semiconductor light source comprises: a base comprising a first metal or metal alloy; and a patterned structure on the base and that comprises a second metal or metal alloy, wherein the patterned structure has a different shape than the base.

Example 21. The semiconductor light source of example 20, wherein the patterned structure is formed of solder and the base comprises a metal or metal alloy having a higher hardness than the solder, or wherein the patterned structure and the base comprise a same metal or metal alloy.

Example 22. The semiconductor light source of any of examples 19 through 21, wherein each pad of the semiconductor light source has a cross feature or four spaced apart posts configured to receive the cross feature.

Example 23. The semiconductor light source of any of examples 19 through 21, wherein each pad of the semiconductor light source has a columnar feature or a wall feature that defines an open interior space configured to receive the columnar feature.

Example 24. The semiconductor light source of any of examples 19 through 21, wherein each pad of the semiconductor light source has a columnar feature or a recess feature configured to receive the columnar feature.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An optoelectronic assembly, comprising:
a plurality of semiconductor light sources, each one of the semiconductor light sources comprising a plurality of pads; and
a driver device configured to drive each one of the semiconductor light sources,
wherein for each pad of each semiconductor light source, the driver device has a corresponding pad facing the pad of the semiconductor light source to form a pair of connectable pads,
wherein for each pair of connectable pads, a first pad of the pair of connectable pads has a first shape and a second pad of the pair of connectable pads has a second shape complementary to the first shape such that the first pad and the second pad form a mated connection when brought into contact with one another.

2. The optoelectronic assembly of claim 1, wherein each pad of the driver device comprises:
a base comprising a first metal or metal alloy; and
a patterned structure on the base and that comprises a second metal or metal alloy,
wherein the patterned structure has a different shape than the base.

3. The optoelectronic assembly of claim 1, wherein each pad of the driver device comprises:
a single patterned metal or metal alloy layer.

4. The optoelectronic assembly of claim 1, wherein each pad of each semiconductor light source comprises:
a base comprising a first metal or metal alloy; and
a patterned structure on the base and that comprises a second metal or metal alloy,
wherein the patterned structure has a different shape than the base.

5. The optoelectronic assembly of claim 4, wherein the patterned structure is formed of solder and the base comprises a metal or metal alloy having a higher hardness than the solder, or wherein the patterned structure and the base comprise a same metal or metal alloy.

6. The optoelectronic assembly of claim 1, wherein for each pair of connectable pads, both the first pad and the second pad of the pair of connectable pads comprises:
a base comprising a first metal or metal alloy; and
a patterned structure on the base and that comprises a second metal or metal alloy,
wherein the patterned structure of the first pad of the pair of connectable pads defines the first shape,
wherein the patterned structure of the second pad of the pair of connectable pads defines the second shape.

7. The optoelectronic assembly of claim 1, wherein the first shape and/or the second shape allows for lateral guidance when bringing the plurality of semiconductor light sources and the driver device together.

8. The optoelectronic assembly of claim 1, wherein for each pair of connectable pads, the first pad or the second pad of the pair of connectable pads has a cross feature and the other one of the first pad or the second pad of the pair of connectable pads has four spaced apart posts configured to receive the cross feature.

9. The optoelectronic assembly of claim 1, wherein for each pair of connectable pads, the first pad or the second pad of the pair of connectable pads has a columnar feature and the other one of the first pad or the second pad of the pair of connectable pads has a wall feature that defines an open interior space configured to receive the columnar feature.

10. The optoelectronic assembly of claim 1, wherein for each pair of connectable pads, the first pad or the second pad of the pair of connectable pads has a columnar feature and the other one of the first pad or the second pad of the pair of connectable pads has a recess feature configured to receive the columnar feature.

11. A driver device, comprising:
a semiconductor substrate;
driver circuitry formed in and/or on the semiconductor substrate and configured to drive a plurality of semiconductor light sources; and
a plurality of pads configured to provide an electrical interface for the driver device to the semiconductor light sources,
wherein for each pad of the driver device, the pad has a first shape that is complementary to a second shape of a semiconductor light source pad to which the pad of the driver device is to be connected, such that the pad of the driver device and the semiconductor light source pad to which the pad of the driver device is to be connected form a mated connection when brought into contact with one another.

12. The driver device of claim 11, wherein each pad of the driver device comprises:
a base comprising a first metal or metal alloy; and
a patterned structure on the base and that comprises a second metal or metal alloy,
wherein the patterned structure has a different shape than the base.

13. The driver device of claim 11, wherein each pad of the driver device comprises:
a single patterned metal or metal alloy layer.

14. The driver device of claim 11, wherein each pad of the driver device has a cross feature or four spaced apart posts configured to receive the cross feature.

15. The driver device of claim 11, wherein each pad of the driver device has a columnar feature or a wall feature that defines an open interior space configured to receive the columnar feature.

16. The driver device of claim 11, wherein each pad of the driver device has a columnar feature or a recess feature configured to receive the columnar feature.

17. A semiconductor light source, comprising:
a semiconductor substrate;
an electroluminescent element included in the semiconductor substrate and configured to emit light in response to an electric current or an electric field; and
a plurality of pads configured to provide an electrical interface for the semiconductor light source to a driver device,
wherein for each pad of the semiconductor light source, the pad has a first shape that is complementary to a second shape of a driver device pad to which the pad of the semiconductor light source is to be connected, such that the pad of the semiconductor light source and the driver device pad to which the pad of the semiconductor light source is to be connected form a mated connection when brought into contact with one another.

18. The semiconductor light source of claim 17, wherein each pad of the semiconductor light source comprises:
a base comprising a first metal or metal alloy; and
a patterned structure on the base and that comprises a second metal or metal alloy,
wherein the patterned structure has a different shape than the base.

19. The semiconductor light source of claim 18, wherein the patterned structure is formed of solder and the base comprises a metal or metal alloy having a higher hardness than the solder, or wherein the patterned structure and the base comprise a same metal or metal alloy.

20. The semiconductor light source of claim 17, wherein each pad of the semiconductor light source has a cross feature or four spaced apart posts configured to receive the cross feature.

21. The semiconductor light source of claim 17, wherein each pad of the semiconductor light source has a columnar feature or a wall feature that defines an open interior space configured to receive the columnar feature.

22. The semiconductor light source of claim 17, wherein each pad of the semiconductor light source has a columnar feature or a recess feature configured to receive the columnar feature.
